(19) United States
(12) Patent Application Publication
(10) Pub. No.: US 2026/0072392 A1
(43) Pub. Date: Mar. 12, 2026

(54) PRINTED BOARD, IMAGE FORMING APPARATUS, AND MOUNTING METHOD

(71) Applicant: CANON KABUSHIKI KAISHA, Tokyo (JP)

(72) Inventor: MASAKI INAGAKI, Shizuoka (JP)

(21) Appl. No.: 19/321,551

(22) Filed: Sep. 8, 2025

(30) Foreign Application Priority Data
Sep. 9, 2024 (JP) 2024-155200

(51) Int. Cl. G03G 15/00; G03G 15/043; H05K 1/11; H05K 3/34

(52) U.S. Cl. CPC G03G 15/80; G03G 15/043; H05K 1/111; H05K 1/116; H05K 3/3447; H05K 2201/09409; H05K 2201/09463; H05K 2201/10303; H05K 2203/162

(57) ABSTRACT

A printed board includes a plurality of through holes including a first through hole and a second through hole are arranged adjacently in an arrangement direction, a plurality of lands disposed corresponding to the plurality of through holds, and one through fourth pads. The plurality of lands includes a first land corresponding to the first through hole and a second land corresponding to the second through hole. The first land is provided with a first land portion electrically connected to the first pad, and a second land portion electrically connected to the second pad and not electrically connected to the first land portion. The second land is provided with a third land portion electrically connected to the third pad, and a fourth land portion electrically connected to the fourth pad and not electrically connected to the third land portion.

### BACKGROUND OF THE INVENTION

### Field of the Invention

The present invention relates to a printed board, an image forming apparatus, and a mounting method, and relates to a printed board which is used for an image forming apparatus which applies an electrophotographic technology, etc. for example.

### Description of the Related Art

In some cases of conventional printed boards, erroneous mounting is prevented by devising transcription of screen printing when mounting a component which includes a plurality of pins on the board (Japanese Laid-Open Patent Application (JP-A) 2011-222878).

### SUMMARY

The present invention includes following configurations.
(1) A printed board comprising: a through hole arrangement in which a plurality of through holes including a first through hole and a second through hole are arranged adjacently in an arrangement direction; a plurality of lands disposed corresponding to the plurality of through holds, respectively, the plurality of lands including a first land corresponding to the first through hole and a second land corresponding to the second through hole; a first pad; a second pad; a third pad; and
a fourth pad, wherein the first land is provided with a first land portion electrically connected to the first pad, and a second land portion electrically connected to the second pad and not electrically connected to the first land portion, and wherein the second land is provided with a third land portion electrically connected to the third pad, and a fourth land portion electrically connected to the fourth pad and not electrically connected to the third land portion.
(2) A printed board comprising: a through hole arrangement in which a plurality of through holes including a first through hole, a second through hole and a third through hole are arranged adjacently in an arrangement direction; a plurality of lands disposed corresponding to the plurality of through holds, respectively, the plurality of lands including a first land corresponding to the first through hole, a second land corresponding to the second through hole, and a third land corresponding to the third through hole; and a component of which one end side is mounted on the second through hole and of which the other end side is mounted on the third through hole, and overlapped with the first through hole as seen in a direction perpendicular to a surface of the printed board.
(3) An image forming apparatus for performing an image formation onto a recording material, the image forming apparatus comprising: a printed board which is described in (1) or (2).

Further features of the present invention will become apparent from the following description of exemplary embodiments with reference to the attached drawings.

### BRIEF DESCRIPTION OF THE DRAWINGS

FIG. 1 is a schematic diagram of a laser beam printer according to a first embodiment and a second embodiment.

FIG. 2 is a perspective view showing printed boards and connector posts of different products according to the first embodiment.

FIG. 3 is a schematic diagram of the printed board according to the first embodiment.

FIG. 4 is a flowchart showing a process of assembling the control board according to the first embodiment into the product.

Part (a), part (b), part (c), part (d), part (e), and part (f) of FIG. 5 are schematic diagrams of the printed board, the connector post, and an inspection circuit according to the first embodiment.

Part (a) and part (b) of FIG. 6 are graphs showing waveforms of a switch, a power source, and a voltmeter of the inspection circuit during an inspection according to the first embodiment.

FIG. 7 is a schematic diagram of the printed board according to the second embodiment.

Part (a) and part (b) of FIG. 8 are schematic diagrams of the printed board on which a lead jumper is mounted according to the second embodiment.

Part (a), part (b), and Part (c) of FIG. 9 are perspective views showing that the printed board and the connector post are mounted in a conventional example.

### DESCRIPTION OF THE EMBODIMENTS

In a configuration of JP-A 2011-222878, in a case that a component is mounted on a board, erroneous mounting may be occurred because a mounting position and a mounting direction are not uniquely determined.

It is an object of the present invention to make it easier to recognize erroneous mounting of the component.

Part (a), part (b), and Part (c) of FIG. 9 will be described below. In part (a), part (b), and Part (c) of FIG. 9, a front view of the connector posts and a top view of through holes of the printed board are shown, and lead pins and the through holes which correspond to the lead pins are connected by dashed lines. In recent years, models of the image forming apparatus are diversified, and in printed boards, there is a method of manufacturing a plurality of models of the printed board by switching a component which is mounted on the same printed board. In the printed board, a through hole (hereinafter, referred to as a “through hole”) for inserting the lead pin which is soldered to the board. The connector post which includes a plurality of lead pins is mounted on the printed board. Incidentally, a housing (not shown) is inserted into the connector post. In the connector post which is mounted on the printed board, at least two types of connector posts with different numbers of the lead pins are designed so that it is possible to mount in the same location, so it is possible to reduce unnecessary wires in a low cost model and reduce the cost.

In part (a), part (b), and Part (c) of FIG. 9, the connector posts which are mounted on a board 700 are shown. 20 pieces of the through holes, for example, through which the lead pins pass, are provided with the board 700. In the following, reference numerals from 701 through 720 are assigned to 20 pieces of the through holes. For example, a connector post 720A, which includes 20 pieces of the lead pins from 1A′l through 20A′l as shown in part (a) of FIG. 9, is mounted on the board 700 which is applied to an image forming apparatus of a high performance model. Here, the lead pins from 1A′l through 20A′l correspond to the through holes from 701 through 720, respectively. On the other hand, a connector post 720B, which includes 16 pieces of the lead pins from 1B′l through 16B′l as shown in part (b) and part (c) of FIG. 9, is mounted on the board 700 which is applied to an image forming apparatus of a low priced model.

Since the board 700 includes 20 pieces of the through holes from 701 through 720, the connector posts 720A which includes 20 pieces of the lead pins from 1A′l through 20A′l is possible to be uniquely mounted on the board 700. On the other hand, in the connector post 720B which includes 16 pieces of the lead pins from 1B′l through 16B′l, the number of the through holes from 701 through 720 in the board 700 is greater than the number of the lead pins from 1B′l through 16B′l in the connector post 720B. Therefore, the mounting position and the direction of the connector post 720B with respect to the board 700 are not uniquely determined, so there is a risk of erroneous mounting. For example, in part (b) of FIGS. 9, 16 pieces of the lead pins from 1B′l through 16B′l of the connector post 720B are inserted into the through holes from 701 through 716 of the board 700. Further, in part (c) of FIGS. 9, 16 pieces of the lead pins from 1B′l through 16B′l of the connector post 720B are inserted into the through holes from 705 through 720 of the board 700.

### First Embodiment

### [Image Forming Apparatus]

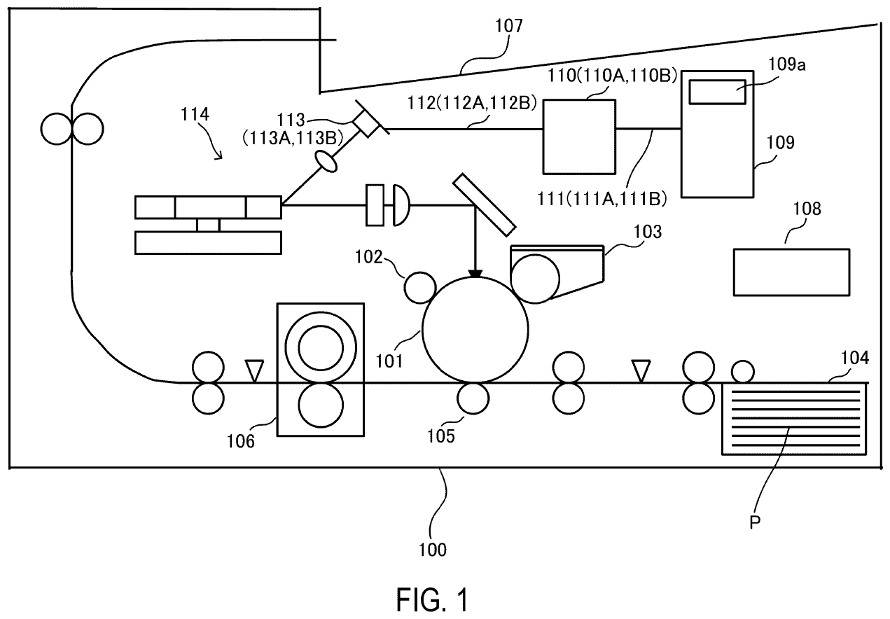

FIG. 1 is a sectional view showing a configuration of a laser beam printer as an example of an image forming apparatus. A laser beam printer 100 (hereinafter referred to as a printer 100) is provided with a photosensitive drum 101 on which an electrostatic latent image is formed, a charging portion 102 which uniformly charges the photosensitive drum 101, and a developing portion 103 which develops the electrostatic latent image which is formed on the photosensitive drum 101 and forms a toner image. Further, the printer 100 is provided with an exposure device 114 which irradiates laser light onto the photosensitive drum 101 by using a laser unit 113 and forms an electrostatic latent image on a surface of the photosensitive drum 101. In the printer 100, the toner image which is formed on the photosensitive drum 101 is transferred to a sheet P which is a recording material which is fed from a cassette 104, by a transfer portion 105. The sheet P onto which the toner image is transferred is conveyed to a fixing device 106, an unfixed toner image is fixed to the sheet P at a fixing device 106, and the sheet P to which the toner image is fixed is discharged to a tray 107. The image forming portion is configured of the photosensitive drum 101, the charging portion 102, the developing portion 103, and the transfer portion 105. Further, the printer 100 is provided with a power source device 108, and the power source device 108 supplies electric power to a driving portion such as a motor and to a control board 109.

The control board 109 includes a CPU 109a as a control portion and controls an image forming operation by the image forming portion, a conveying operation of the sheet P, etc. In the image forming operation, a signal which is output from the CPU 109a is transmitted from the control board 109 to a laser control board 110 via an electric wire 111. The laser control board 110 controls lighting of a laser unit 113 via an electric wire 112 based on the signal. Incidentally, the image forming apparatus to which the present invention is applied is not limited to a configuration shown in FIG. 1.

Specification of the laser unit 113 are different in the first embodiment, and a laser unit 113A and a laser control board 110A are used in a product A, and a laser unit 113B and a laser control board 110B are used in a product B. Similarly, for the electric wire 111 and the electric wire 112, an electric wire 111A and an electric wire 112A are used in the product A, and an electric wire 111B and an electric wire 112B are used in the product B. In the first embodiment, the product A has a higher performance than the product B, and the cost of the product B is reduced since the number of the electric wires of the electric wire 111A is 20 and the number of the electric wires of the electric wire 111B is 16.

### [Control Board 109]

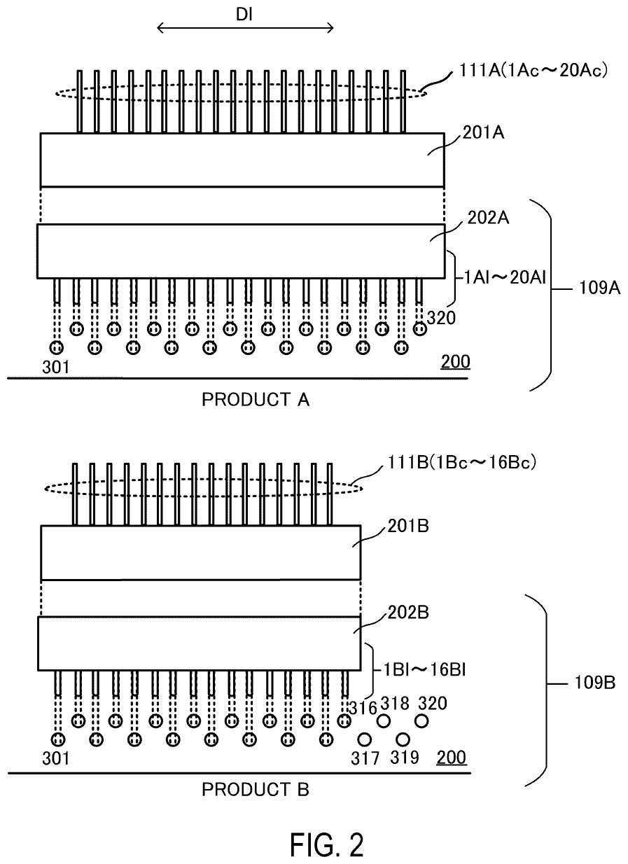

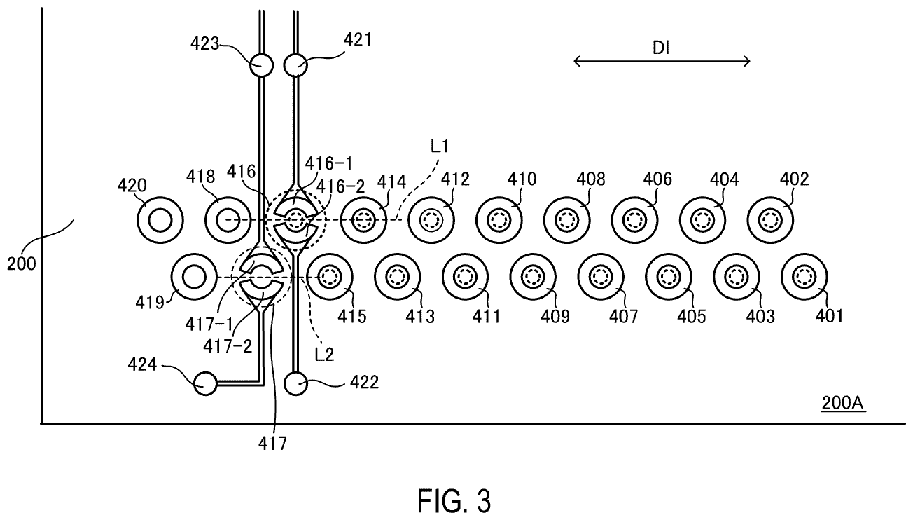

Each part of the control boards 109 of the product A and the product B in the first embodiment is shown in FIG. 2. In FIG. 2, a front view of a connector housing and the connector posts and a top view of the through holes of the printed board are shown, and the lead pins and the through holes which correspond to the lead pins are connected by dashed lines. In the product A and the product B, the same printed board 200 is used, and by changing the specification of the component which is mounted and not mounting the component which is not used, the control board 109A which is optimal for the product A and the control board 109B which is optimal for the product B are manufactured, respectively. The printed board 200 is provided with the plurality of through holes, for example 20 through holes, through which the lead pins pass, and reference numerals from 301 through 320 are assigned to these. The through holes from 301 through 320 (through hole arrangement) are disposed in two rows so that the through holes 301, 303, . . . , 319 with odd reference numerals and the through holes 302, 304, . . . , 320 with even reference numerals are adjacent to each other in a staggered arrangement on the printed board 200. Further, in the printed board 200, a surface on which the component is soldered, in other words, a surface which is opposite to a surface on which the component is mounted, is defined as a solder surface 200A (see FIG. 3). Furthermore, a longitudinal direction of the connector housing and the connector post which will be described below is defined as a Dl. The longitudinal direction Dl is also an arrangement direction (array direction) of the lead pins.

In the product A, the connector housing 201A and the connector post 202A are used to connect the electric wire 111A and the control board 109A, and the connector post 202A is mounted on the printed board 200 by soldering and the control board 109A is formed. The connector housing 201A includes 20 pieces of the contact pins from 1Ac through 20Ac, and the contact pins from 1Ac through 20Ac are electrically connected to the electric wire 111A. The connector post 202A, which is a first connector, includes 20 pieces of the lead pins from 1Al through 20Al, and the lead pins from 1Al through 20Al are soldered to the through holes from 301 through 320, respectively. Incidentally, the lead pins from 1Al through 20Al are also arranged in two rows to fit the through holes from 301 through 320 in a staggered arrangement.

Incidentally, the number of the through holes from 301 through 320 of the printed board 200 is 20, which is the same number as the number of the lead pins from 1Al through 20Al of the connector post 202A. Therefore, in the control board 109A, the connector post 202A which includes 20 pieces of the lead pins from 1Al through 20Al is possible to be uniquely mounted.

On the other hand, in the product B, the connector housing 201B and the connector post 202B are used to connect the electric wire 111B and the control board 109B, and the connector post 202B is mounted on the printed board 200 by soldering and the control board 109B is formed. The connector housing 201B includes 16 pieces of the contact pins from 1Bc through 16Bc, and the contact pins from 1Bc through 16Bc are electrically connected to the electric wire 111B. The connector post 202B as a second connector includes 16 pieces of the lead pins from 1Bl through 16Bl. Similar to the product A, the number of the through holes from 301 through 320 of the printed board 200 is 20, and the number of the lead pins from 1Bl through 16Bl of the connector post 202B is less than the number of the through holes from 301 through 320. Incidentally, the lead pins from 1Bl through 16Bl are also arranged in two rows to fit the through holes from 301 through 320 in the staggered arrangement.

Therefore, in the control board 109B, a mounting location of the connector post 202B, which includes 16 pieces of the lead pins from 1Bl through 16Bl, with respect to the printed board 200, is not uniquely determined. Incidentally, in FIG. 2, the lead pins from 1Bl through 16Bl of the connector post 202B are shown as an example of mounting on the through holes from 301 through 316, and this state is a correct mounting position. However, as the mounting position of the connector post 202B on the printed board 200, there may be a case of mounting on the through holes from 303 through 318, or a case of mounting on the through holes from 305 through 320, for example.

Incidentally, among the lead pins from 1Bl through 16Bl of the connector post 202B, the lead pin 1Bl may be the smallest pin and the lead pin 16Bl may be the largest pin. The largest pin (16Bl) is a lead pin (first lead pin), which is positioned at one end portion of the connector post 202B with respect to the longitudinal direction Dl, among the plurality of lead pins in which the connector post 202B includes. The smallest pin (1Bl) is a lead pin (second lead pin), which is positioned at the other end portion of the connector post 202B with respect to the longitudinal direction Dl, among the plurality of lead pins in which the connector post 202B includes. Incidentally, the lead pin 2Bl may be the smallest pin, and the lead pin 15Bl may be the largest pin. Further, a correct mounting state is defined as a first state, in which the lead pin 16Bl of the connector post 202B passes through the through hole 316 and the lead pin 1Bl passes through the through hole 301. An erroneous mounting state is defined as a second state, in which the lead pin 16Bl of connector post 202B passes through the through hole which is different from the through hole 316, and the lead pin 1Bl passes through the through hole which is different from the through hole 301.

### [Printed Board 200]

FIG. 3 shows a schematic diagram of the solder surface 200A of the printed board 200 in the first embodiment. Numbers of the through holes from 301 through 320 in FIG. 2 correspond to numbers of lands from 401 through 420 (plurality of lands) in FIG. 3. For example, the through hole 301 corresponds to the land 401, and the through hole 320 corresponds to the land 420. That is, the printed board 200 includes the lands from 401 through 420 with copper foil surrounding the through holes from 301 through 320 on a side of the solder surface 200A.

In the first embodiment, the land 416 (first land) corresponding to the lead pin 16Bl, which is the largest pin of the connector post 202B, is divided into two lands of a land 416-1 (first land portion) and a land 416-2 (second land portion). In a direction along a surface of the printed board 200 and in a crossing direction which crosses an arrangement direction, the land 416-1 and the 416-2 are disposed in different positions. In the crossing direction, each of the land 416-1 and the land 416-2 is between a pad 421 and a pad 422. A shortest distance between the land 416-1 and the land 416-2 is 0.3 mm or more. By configuring in this way, a chance of the land 416-1 and the land 416-2 being soldered when soldering the land 416 and the lead pin is reduced. The through hole 316 corresponding to the land 416 is a first through hole.

At this time, a imaginary line L1 which divides two lands of the land 416-1 and the land 416-2 is parallel to the longitudinal direction Dl (flow direction in the first embodiment). And the land 416-1 is electrically connected to the pad 421 (first pad) with copper foil, and the land 416-2 is electrically connected to the pad 422 (second pad) with copper foil.

Furthermore, in the longitudinal direction Dl, the land 417 (second land) which is adjacent to the land 416 is divided into two lands of the land 417-1 (third land portion) and the land 417-2 (fourth land portion). In the direction along the surface of the printed board 200 and in the crossing direction which crosses the arrangement direction, the lands 417-1 and 417-2 are disposed at different positions. In the crossing direction, each of the land 417-1 and the land 417-2 is between a pad 423 and a pad 424. The shortest distance between the land 417-1 and the land 417-2 is 0.3 mm or more. By configuring in this way, the chance of the land 417-1 and the land 417-2 being soldered when soldering the land 417 and the lead pin is reduced. Incidentally, the through hole 317 corresponding to the land 417 is a second through hole.

At this time, a imaginary line L2 which divides two lands of the land 417-1 and the land 417-2 is also parallel to the longitudinal direction Dl (flow direction in the first embodiment). And the land 417-1 is electrically connected to the pad 423 (third pad) with copper foil, and the land 417-2 is electrically connected to the pad 424 (fourth pad) with copper foil. The pads from 421 to 424 are electrodes which are contact points of an inspection device which electrically detects a mounting defect of the printed board, such as an in-circuit tester, during inspection of a mounting defect of the printed board 200.

Incidentally, in the first embodiment, the correct mounting position of the connector post 202B of the product B is set to the through holes from 301 through 316, however, it is not limited to this. The correct mounting position may be set to the through holes from 303 through 318 or the through holes from 305 through 320.

Further, in the first embodiment, the pads from 421 through 424 are provided only on one end portion, however, they may be provided only on the other end portion or on both end portions. In this case, the through hole through which the lead pin 16Bl passes is defined as a first through hole, the through hole through which the lead pin 1Bl passes is defined as a second through hole, the land of the first through hole is defined as a first land, and the land of the second through hole is defined as a second land. And the land which is on a side of one end portion in the arrangement direction with respect to the first land and/or the land which is on a side of the other end portion with respect to the second land is defined as a third land. And the third land may be the land which is adjacent to the first land and/or the second land as shown in FIG. 3 which is described above.

### [Mounting of Control Board 109B]

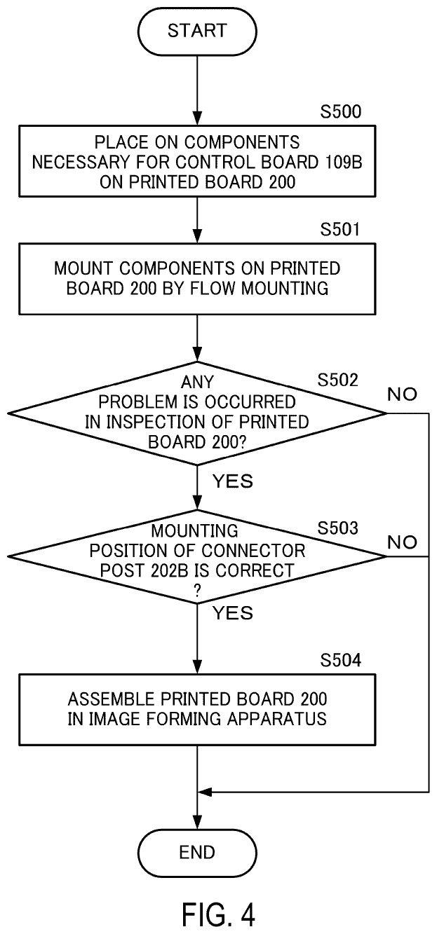

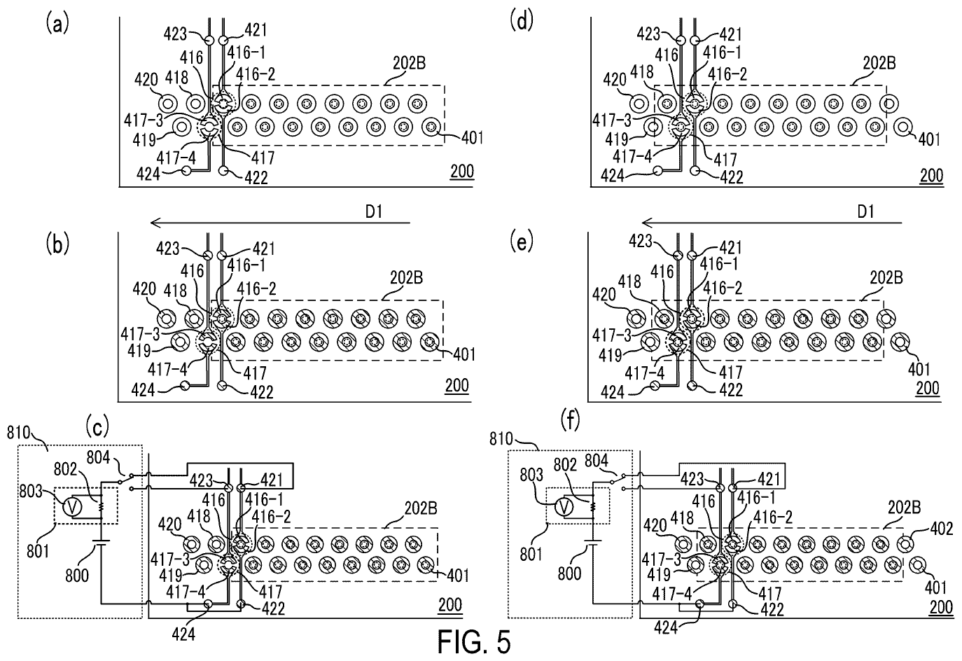

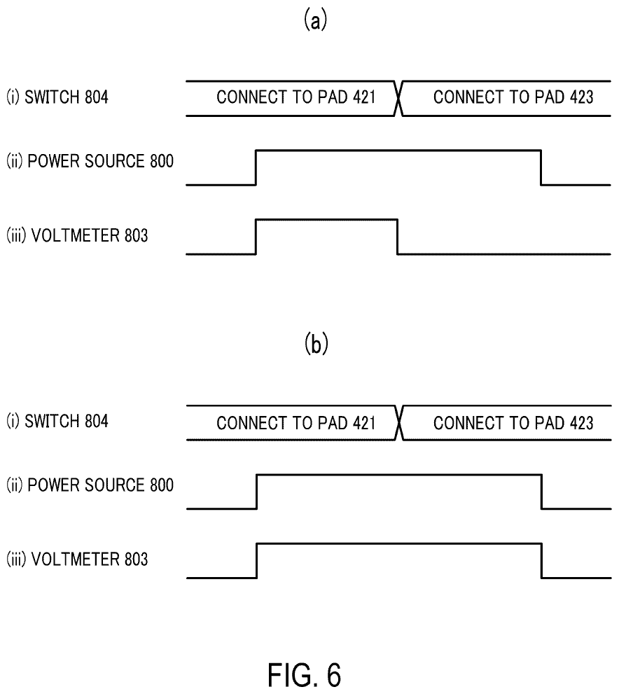

FIG. 4 shows a flow (mounting method) for mounting the control board 109B on the product B. In S500, a component which is necessary for the circuit of the control board 109B is placed on the printed board 200 (first step). In the embodiment, the connector post 202B is placed so that the lead pins are inserted into the lands from 401 through 416 of the printed board 200. In S501, solder is applied to the component which is placed on the printed board 200. In the embodiment, solder is applied by a flow mounting (second step). The flow mounting of the connector post 202B will be specifically described below.

In S502, inspection of the printed board 200 is performed. In the inspection, whether the component is correctly mounted on the printed board 200 and whether any defects are occurred on the mounted component (third step, fourth step). In a case that an inspection result is normal, proceed to S503. In S503, the connector post 202B is inspected whether it is mounted in a correct position. In a case that it is mounted in the correct position, proceed to S504. It will be specifically described below. In S504, the printed board 200 in which the component is correctly mounted is assembled into the image forming apparatus as the control board 109B. Incidentally, in a case that there is a problem with the inspection result in S502, or in a case that the mounting position is not correct in S503, the flowchart in FIG. 4 is terminated.

In this way, the mounting method for mounting the mounting component on the printed board 200 includes the first step for inserting the plurality of lead pins into the plurality of through holes, the second step for soldering the plurality of lead pins on the plurality of lands, the third step for connecting the inspection device to the first pad and the second pad, and measuring a current signal and the fourth step for connecting the inspection device to the third pad and the fourth pad and measuring a current signal.

### [Flow Mounting of the Printed Board 200]

In S501 in FIG. 4, a process of flow mounting of the connector posts 202B on the printed board 200 will be described. Part (a), part (b), part (c), part (d) and part (f) of FIG. 5 are schematic diagrams of the printed board 200 and the connector post 202B in each process which is shown in FIG. 4. Part (a) of FIG. 5 is a schematic diagram of the printed board 200 in which the connector post 202B is inserted into the correct land in the process of S500. The lead pins from 1Bl through 16Bl of the connector post 202B are inserted into the lands from 401 through 416.

Part (b) of FIG. 5 is a schematic diagram of the printed board 200 and the connector post 202B in which flow mounting is performed from a state in part (a) of FIG. 5. The flow direction during flow mounting is the longitudinal direction Dl of the connector post 202B. When the connector post 202B is flow mounted, the lead pin 16Bl of the connector post 202B is soldered to the land 416-1, and the lead pin 16Bl of the connector post 202B is soldered to the land 416-2, in the land 416. Therefore, since the land 416-1 and the land 416-2, which are divided into two lands, are electrically connected by the same lead pin 16Bl, the pad 421 and the pad 422 are electrically connected.

On the other hand, since the land 417 does not include a 17th lead pin of the connector post 202B, even when flow mounting is performed, the land 417-1 and the land 417-2 are not electrically connected by the lead pin. Therefore, the pad 423 and the pad 424 are also not electrically connected.

That is, when the land 416 and the land 417 are divided into two parts, in a case that there is the lead pin of the connector post 202B, the pads which are connected to the divided lands are electrically connected to each other. On the other hand, in a case that there is no lead pin of the connector post 202B, the pads which are connected to each of the lands which are divided become electrically disconnected.

Part (d) of FIG. 5 is a schematic diagram of the printed board 200 and the connector post 202B in which the connector post 202B is inserted into a wrong land in the process of S500. In the embodiment, the lead pins from 1Bl through 16Bl of the connector post 202B are inserted into the lands from 403 through 418.

Part (e) of FIG. 5 is a schematic diagram of the printed board 200 and the connector post 202B in which flow mounting is performed from a state in part (d) of FIG. 5. The flow direction during flow mounting is the longitudinal direction Dl of the connector post 202B. The land 416 in part (e) of FIG. 5 is connected to the land 416-1 and the land 416-2 by solder via the lead pin (specifically, the lead pin 14Bl) similar to the land 416 in part (b) of FIG. 5. Therefore, the pad 421 and the pad 422 are electrically connected.

On the other hand, the land 417 in part (e) of FIG. 5 differs from the land 417 in part (b) of FIG. 5 in that the lead pin (specifically, the lead pin 15Bl) is inserted.

Therefore, the land 417-1 and the land 417-2 are connected by solder via the lead pin.

Thus, the pad 423 and the pad 424 are electrically connected.

### [Flow Mounting of Printed Board 200]

A mounting inspection of the connector post 202B in S503 will be described. Part (c) of FIG. 5 is a schematic diagram showing a state when the printed board 200, in which the connector post 202B is correctly mounted, is connected to the inspection circuit 810. The inspection circuit 810 is connected in series with a power source 800 and a current detection circuit 801. The inspection circuit 810 is configured such that one end is connected to the pad 422 and the pad 424, and the other end is connected to the pad 421 and the 423, and it is possible to switch connection between the pad 421 and the pad 423 by a switch 804. More specifically, it is possible to switch between a state in which the inspection circuit 810 is connected to the pad 421 and a state in which the inspection circuit 810 is connected to the pad 423 by the switch 804. In part (c) of FIG. 5, the switch 804 is connected to the pad 421. In the embodiment, the current detection circuit 801 is configured such that a resistor 802 and a voltmeter 803 are connected in parallel.

Part (a) of FIG. 6 shows a waveform when the printed board 200 in which the connector post 202B is correctly mounted as shown in part (c) of FIG. 5 is inspected. In part (a) of FIG. 6, (i) indicates a state of the switch 804 (connect to the pad 421, or connect to the pad 423), (ii) indicates whether the power source 800 is on or off, and (iii) indicates a level (H, L) (electrical signal) of the voltmeter 803. A horizontal axis indicates time.

First of all, the switch 804 is connected to the pad 421, the power source 800 is turned on, and voltage is applied. At this time, since the pad 421 and the pad 422 are electrically connected, current flows through the resistor 802 and voltage is applied to the voltmeter 803. After that, the switch 804 is switched to connect to the pad 423, and voltage is applied from the power source 800. At this time, since the pad 423 and the pad 424 are not electrically connected, the current does not flow through the resistor 802, and the voltage is not applied to the voltmeter 803.

Part (f) of FIG. 5 is a schematic diagram showing a state that the printed board 200, on which the connector post 202B is erroneously mounted, is connected to the inspection circuit 810. The inspection circuit 810 is the same as that in part (c) of FIG. 5, and the description will be omitted. Part (b) of FIG. 6 shows a waveform when the printed board 200 in which the connector post 202B is erroneously mounted as shown in part (f) of FIG. 5 is inspected. From (i) through (iii) in part (b) of FIG. 6 are the same as those in part (a) of FIG. 6.

First of all, the switch 804 is connected to the pad 421, the power source 800 is turned on, and the voltage is applied. At this time, since the pad 421 and the pad 422 are electrically connected, the current flows through the resistor 802 and the voltage is applied to the voltmeter 803. After that, the switch 804 is switched to connect to the pad 423, and the voltage is applied from the power source 800. At this time, unlike part (a) of FIG. 6, since the pad 423 and the pad 424 are electrically connected, the current flows through the resistor 802 and the voltage is applied to the voltmeter 803.

Therefore, since the voltage of the voltmeter 803 differs when the voltage is applied between the pad 423 and the pad 424, it is possible to detect the erroneous mounting of the connector post 202B. Further, since it is possible to conduct the inspection together with mounting inspection of other components, no large initial investment is required. In the first embodiment, it is possible to detect that the mounting position is correct by confirming that the adjacent 17th lead pin does not exist corresponding to the connector post 202B which includes 16 pieces of the lead pins from 1Bl through 16Bl.

Furthermore, it may be confirmed that the lead pin 1Bl (second lead pin) and the lead pin 16Bl (first lead pin) of the connector post 202B exist and the 17th lead pin does not exist by dividing the land 401 into two portions. In this way, it is possible to confirm that the number of the lead pins of the connectors which are mounted is correct that is 16. Further, in a case that it is possible to correctly manage the mounting component of the connector post 202B, only one piece of the land, which is adjacent to the land to which the lead pin is connected and to which the lead pin is not connected, may be divided into two portions. Further, the total area (surface area) of the two divided lands may be larger than the area (surface area) of the other land (third land) which is not divided. Therefore, since it is possible to reduce decrease in connection strength by dividing the land, it is preferable that the area of the land which is divided is larger than the area of the land which is not divided. Further, in the flow mounting, it is possible to reduce occurrence of solder bridges in a case that the lead pin of the connector post 202B does not exist, when the land is divided into two portions in parallel to the flow direction, so it is preferable to divide in parallel to the flow direction. Further, in the first embodiment, the land is divided into two portions, however, it is not limited to this. The land may be divided into two or more electrodes. And the two or more divided electrodes may only be electrically connected to the pads (contact points), respectively. Further, the through holes from 301 through 320 are arranged in a staggered arrangement, however, the through holes 301, 303, ..., 319 with odd reference numerals and the through holes 302, 304,. 320 with even reference numerals are disposed in two rows so that they are in the staggered arrangement on the printed board 200. Furthermore, in the first embodiment, the configuration is adapted to the lead type connector, however, it is not limited to the lead type and it is also possible to implement for a surface mount type component.

As described above, according to the first embodiment, by dividing the land which mounts the connector post into two portions and connecting each of the divided lands to each of the pads, it is possible to determine whether or not the lead pins of the connector post are mounted on the land. By applying such a configuration, it is possible to detect erroneous mounting of the connector post with a small number of pins at low cost.

As described above, according to the first embodiment, it is possible to recognize erroneous mounting of the component.

### Second Embodiment

The image forming apparatus which is applied in a second embodiment is the same as that in the first embodiment, and the description will be omitted. Further, the laser units 113A and 113B, the electric wires 112A and 112B, the laser control boards 110A and 110B, the electric wires 111A and 111B, the connector housings 201A and 201B, and the connector posts 202A and 202B of the product A and the product B which are used in the second embodiment are also similar. For this reason, these descriptions will also be omitted.

### [Printed Board 500]

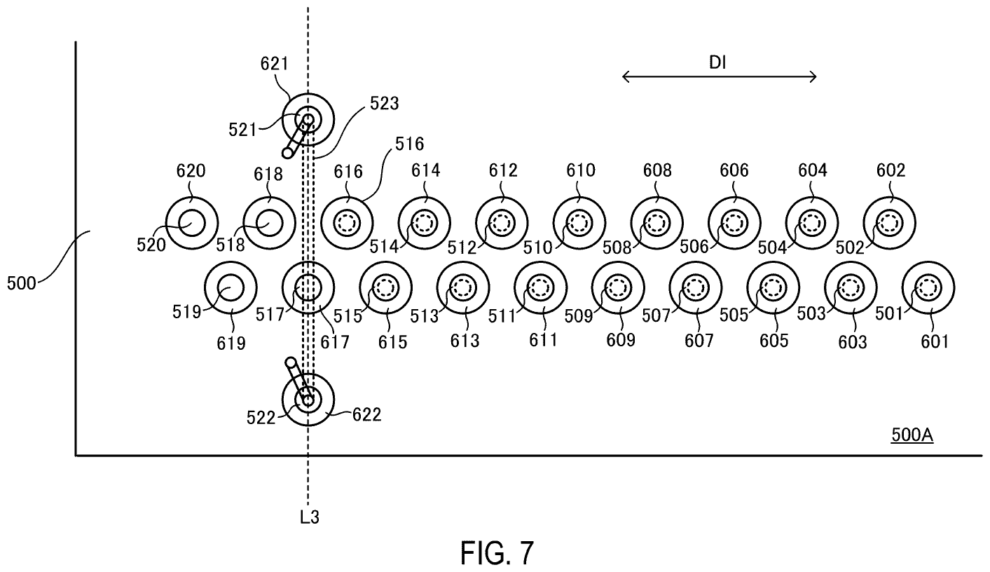

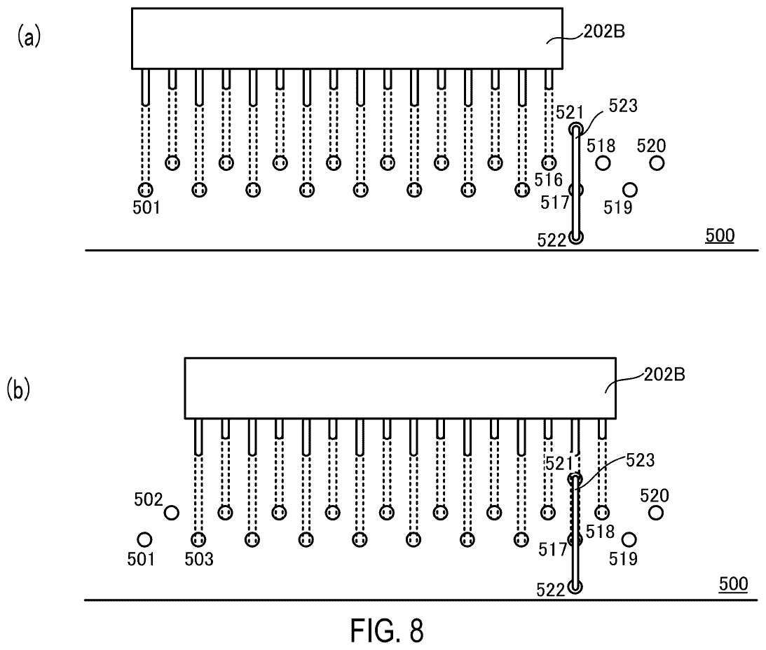

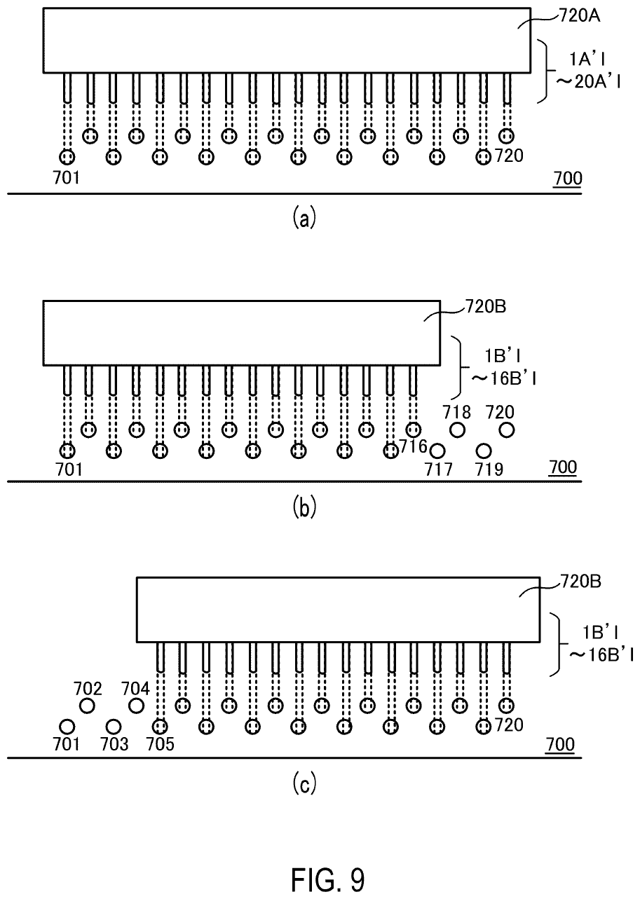

In the second embodiment, a printed board 500 is applied to the control board 109A and the control board 109B. FIG. 7 shows a schematic diagram of a solder surface 500A of the printed board 500 in the second embodiment. In the printed board 500, through holes from 501 through 520 (a plurality of through holes) and lands from 601 through 620 (a plurality of lands) are formed, in order to mount the connector post 202 A and the connector post 202B. The through holes from 501 through 520 are similar to the through holes from 301 through 320 in the first embodiment.

In the second embodiment, through holes 521 and 522 which are different from the through holes from 501 through 520 and a land 621 (fourth land) and a land 622 (fifth land) which are different from the lands from 601 through 620 are formed on the printed board 500. The land 621 and the land 622 are disposed so that a imaginary line L3 which connects the land 621 and the land 622 crosses a longitudinal direction Dl (direction in which the lead pins are arranged). In the second embodiment, the lands 621 and 622 are formed so that the imaginary line L3 is perpendicular to the longitudinal direction Dl.

In the second embodiment, a component which includes lead pins which go through the land 621 and the land 622 is mounted on the printed board 500.

Part (a) and part (b) of FIG. 8 are schematic diagrams showing that a lead jumper 523 (jumper wire) is mounted so as to cover (or straddle) the through hole 517 of the printed board 500 in the second embodiment. Part (a) of FIG. 8 is a schematic diagram showing that the connector post 202B is being mounted in the correct mounting position, and part (b) of FIG. 8 is a schematic diagram showing that the connector post 202B is being mounted in an erroneous mounting position.

The lead jumper 523 is a component whose one end is mounted in the through hole 518 which is the second through hole, and whose the other end is mounted in the through hole 522 which is a third through hole. The lead jumper 523 is the component which overlaps the through hole 517 which is the first through hole, when it is viewed in a direction perpendicular to the surface of the printed board 200.

As shown in part (a) of FIG. 8, when the connector post 202B is mounted in the correct mounting state (first state) and the lead jumper 523 is mounted on the land 621 and the land 622, the lead jumper 523 covers the land 617 (third land). In other words, the lead jumper 523 is arranged in a position in which it interferes with the connector post 202B when the connector post 202B is being mounted in the erroneous state (second state) as shown in part (b) of FIG. 8.

The lead jumper 523 is mechanically mounted, so the erroneous mounting does not occur. By mounting the lead jumper 523 in advance, it is not possible to insert the connector post 202B into the through hole 517. Therefore, it is possible to insert the lead pins from 1Bl through 16Bl of the connector post 202B into the through holes from 501 through 516, in other words, it is possible to insert at the correct positions and it is possible to surely prevent the erroneous mounting.

In the second embodiment, the lead jumper 523 is arranged so as to interfere with only one side of the connector, however, it is not limited to this. For example, in a case that there are empty pins at both ends, the lead jumpers may be mounted at both ends of the through holes. And the land which is on a side of one end portion in the arrangement direction with respect to the first land and/or the land which is on a side of the other end portion with respect to the second land is defined as the third land, the lead jumper may be provided so as to cover the third land. In the second embodiment, a hole for inserting the lead jumper is newly provided, however, it is not limited to this. The lead jumper may be inserted directly into the through hole of the connector which is not used. For example, the lead jumper may be inserted into the through hole 517 and the through hole 518.

In the second embodiment, the lead jumper 523 is arranged so as to block the through hole 517, however, it is not limited to this. It may only prevent the connector from mounting at the erroneous position by existence of the lead jumper, and it is not always necessary to cover the through hole. For example, it is also possible to prevent the connector from inserting by using a thickness of the lead jumper.

In the second embodiment, the lead jumper is used, however, any component which is able to interfere with the erroneous insertion of the connector may be used, for example, an electronic component to which a lead is attached may be used instead of the lead jumper. Further, the through hole may be blocked by using a large chip component. In this case, it is preferable to use the component which is mechanically mounted. In the second embodiment, the configuration is adapted to the lead type connector, however, it is not limited to the lead type and it is also possible to implement for the surface mount type component.

As described above, according to the second embodiment, in a case of mounting the connector post with the small number of pins, the component is arranged in advance at the position which interferes with the connector post. By applying such a configuration, it is possible to provide a means of surely preventing erroneous mounting of the connector post, since an operator is not able to insert the connector post.

As described above, according to the second embodiment, it is possible to recognize the erroneous mounting of the component.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-155200 filed on Sep. 9, 2024, which is hereby incorporated by reference herein in its entirety.

What is claimed is:

1. A printed board comprising:
a through hole arrangement in which a plurality of through holes including a first through hole and a second through hole are arranged adjacently in an arrangement direction;
a plurality of lands disposed corresponding to the plurality of through holds, respectively, the plurality of lands including a first land corresponding to the first through hole and a second land corresponding to the second through hole;
a first pad;
a second pad;
a third pad; and
a fourth pad,
wherein the first land is provided with a first land portion electrically connected to the first pad, and a second land portion electrically connected to the second pad and not electrically connected to the first land portion, and
wherein the second land is provided with a third land portion electrically connected to the third pad, and a fourth land portion electrically connected to the fourth pad and not electrically connected to the third land portion.

2. The printed board according to claim 1, wherein the plurality of lands includes a third land, and
wherein each of surface areas of the first land portion, the second land portion, the third land portion and the fourth land portion is smaller than a surface area of the third land.

3. The printed board according to claim 2, wherein in a crossing direction along a surface of the printed board and crossing to the arrangement direction, the first land portion and the second land portion are disposed in different positions, and
wherein in the crossing direction, the third land portion and the fourth land portion are disposed in different positions.

4. The printed board according to claim 3, wherein in the shortest distance between the first land portion and the second land portion is 0.3 mm or more, and
wherein in the shortest distance between the third land portion and the fourth land portion is 0.3 mm or more.

5. The printed board according to claim 4, wherein in the crossing direction, each of the first land portion and the second land portion is between the first pad and the second pad, and
wherein in the crossing direction, each of the third land portion and the fourth land portion is between the third pad and the fourth pad.

6. A printed board comprising:
a through hole arrangement in which a plurality of through holes including a first through hole, a second through hole and a third through hole are arranged adjacently in an arrangement direction;
a plurality of lands disposed corresponding to the plurality of through holds, respectively, the plurality of lands including a first land corresponding to the first through hole, a second land corresponding to the second through hole, and a third land corresponding to the third through hole; and
a component of which one end side is mounted on the second through hole and of which the other end side is mounted on the third through hole, and overlapped with the first through hole as seen in a direction perpendicular to a surface of the printed board.

7. The printed board according to claim 6, wherein in a crossing direction along the surface of the printed board and crossing to the arrangement direction, the first land is positioned between the second land and the third land.

8. The printed board according to claim 7, wherein in the arrangement direction, at least of the first land, at least of the second land and the third land are positioned at a same position.

9. The printed board according to claim 8, wherein the component is a jumper wire.

10. An image forming apparatus for performing an image formation onto a recording material, the image forming apparatus comprising:
a printed board according to claim 1.

11. An image forming apparatus according to claim 10, further comprising:
a photosensitive drum;
an exposure device configured to form an electrostatic latent image on the photosensitive drum; and
a control portion configured to control the exposure device,
wherein the control portion is included in the printed board.

12. An image forming apparatus for performing an image formation onto a recording material, the image forming apparatus comprising:
a printed board according to claim 6.

13. An image forming apparatus according to claim 12, further comprising:
a photosensitive drum;
an exposure device configured to form an electrostatic latent image on the photosensitive drum; and
a control portion configured to control the exposure device,
wherein the control portion is included in the printed board.

14. A mounting method for mounting a mounting component on a substrate,
wherein the mounting component is provided with a plurality of lead pins,
wherein the substrate includes:
a plurality of through hole including a first through hole and a second through hole;
a plurality of lands disposed corresponding to the plurality of through holds, respectively;
a first pad;
a second pad;
a third pad; and
a fourth pad,
wherein the plurality of lands includes:
a first land to which one of lead pins, of the plurality of lead pins to be mounted on the first through hole, is soldered, the first land is provided with a first land portion electrically connected to the first pad, and a second land portion electrically connected to the second pad and not electrically connected to the first land portion; and
a second land to which one of lead pins, of the plurality of lead pins to be mounted on the second through hole, is soldered, the second land is provided with a third land portion electrically connected to the third pad, and a fourth land portion electrically connected to the fourth pad and not electrically connected to the third land portion, and
wherein the mounting method includes:
a first step for inserting the plurality of lead pins into the plurality of through holes;
a second step for soldering the plurality of lead pins on the plurality of lands;
a third step for connecting an inspection device to the first pad and the second pad, and measuring a current signal; and
a fourth step for connecting the inspection device to the third pad and the fourth pad, and measuring a current signal.
